(19) United States
(12) Patent Application Publication
(10) Pub. No.: US 2008/0254376 A1
(43) Pub. Date: Oct. 16, 2008

(54) PHASE-SHIFTING MASK AND METHOD OF FABRICATING SAME

(75) Inventors: Cheng-Ming Lin, Siluo Township (TW); Boming Hsu, Tainan City (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/734,163

(22) Filed: Apr. 11, 2007

(51) Int. Cl. G03F 1/00

(52) U.S. Cl. 430/5

(57) ABSTRACT

A phase-shifting mask is fabricated using two separate exposure processes. The mask includes a substrate and a device pattern area above the substrate. The mask has a mask pattern defining boundaries of the device pattern area and an administrative pattern area defining boundaries of the mask pattern.

### BACKGROUND

The present disclosure relates in general to integrated circuit fabrication, and more particularly, to a phase-shifting mask (PSM).

Increasingly, chip makers are designing integrated circuits with critical dimension (CD) tolerances as tight as 32 nm technology rule. To meet such reduced feature sizes, phase shifting masks, instead of binary masks, are increasingly being used by chip makers. Conventional light sources and lenses, or binary masks cannot consistently transfer a chip design with such narrow device linewidths to a wafer. Phase shifting masks are effective in accommodating the printing of smaller device linewidths of wafers because such masks sharpen the light's effects on a resist during photoexposure.

Phase shifting masks conventionally include a mask layer, such as molybdenum silicide, deposited on a quartz substrate. The mask layer is then patterned, e.g., dry etched, to define a circuit pattern that is to be printed on a wafer. Conventional PSM fabrication techniques utilize a single exposure with a positive photoresist to mask a device pattern. A raster scan technique, such as laser lithography, is used to pattern the positive photoresist. In some applications, this can result in approximately 100 minutes of exposure time per PSM.

Therefore, it would be desirable to have a PSM fabrication process that utilizes more efficient patterning tools, such as vector scanning, to mask a device pattern thereby improving fabrication throughput.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the appended drawings illustrate only typical embodiments of this invention and are therefore not to be considered limiting in scope, for the invention may apply equally well to other embodiments.

FIGS. 1a through 1h are sectional views of one embodiment of a mask at various fabrication stages according to one aspect of the present invention.

FIGS. 2a and 2b are top and sectional views, respectively, of a mask constructed according to the fabrication steps described with respect to FIGS. 1a through 1h.

### DETAILED DESCRIPTION

For the purposes of promoting an understanding of the principles of the invention, reference will now be made to the embodiments, or examples, illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates. Furthermore, the depiction of one or more elements in close proximity to each other does not otherwise preclude the existence of intervening elements. Also, reference numbers may be repeated throughout the embodiments, and this does not by itself indicate a requirement that features of one embodiment apply to another embodiment, even if they share the same reference number.

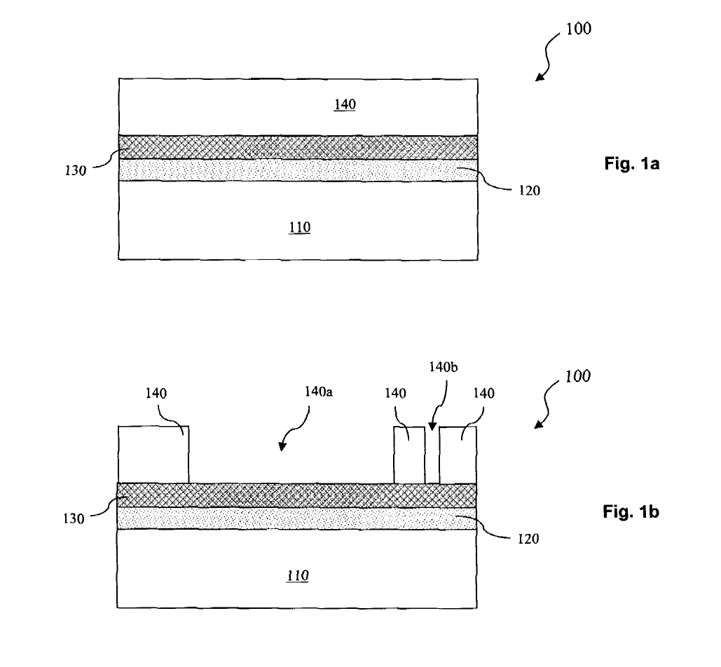

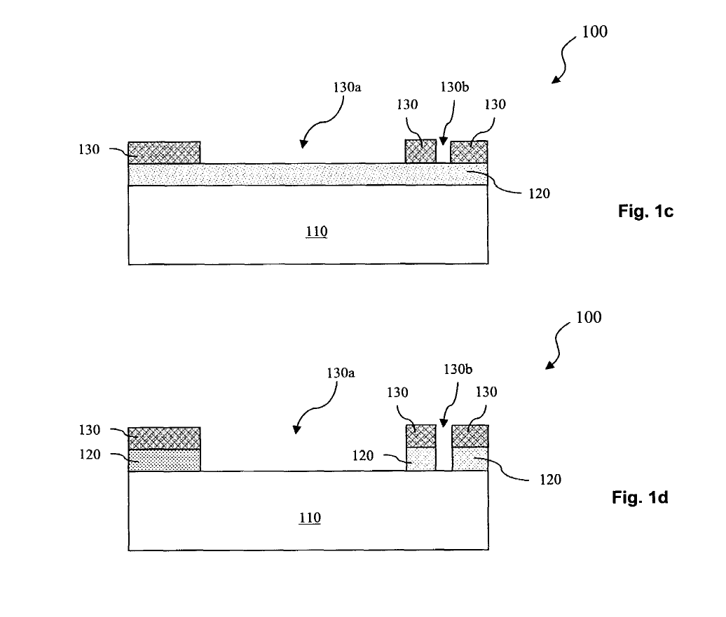

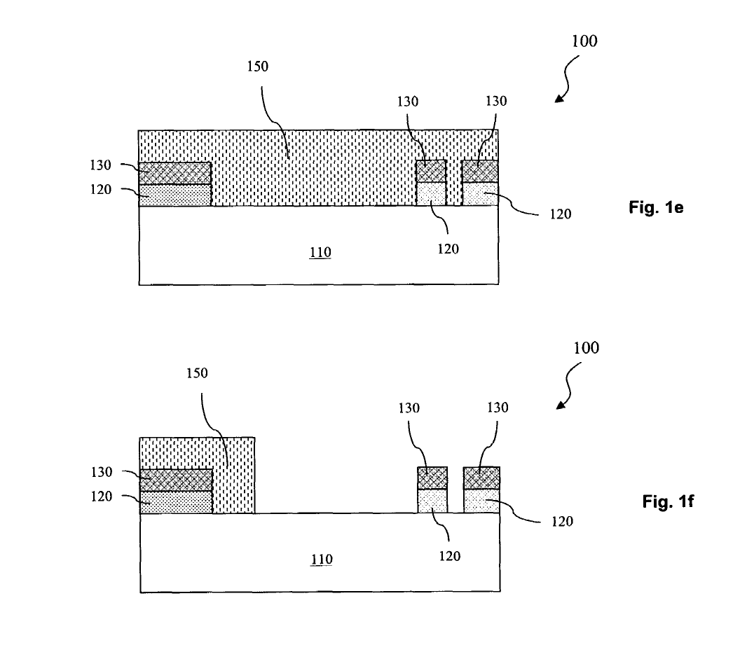

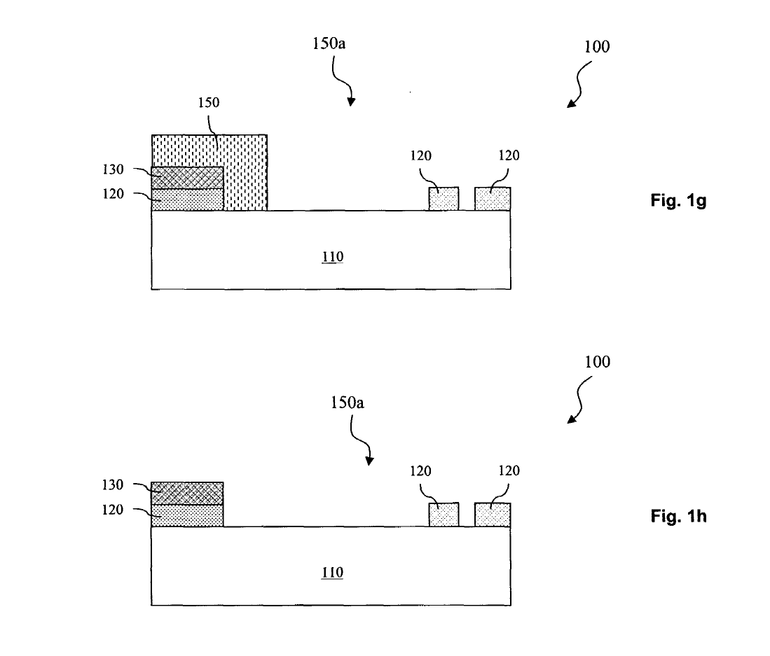

FIGS. 1a through 1h are sectional views of an embodiment of a mask (mask, or reticle, collectively referred to as mask) 100 constructed according to aspects of the present disclosure.

Referring to FIG. 1a, the mask 100 may be a portion of a mask utilized in fabrication of a semiconductor wafer. The mask 100 includes a substrate 110. The substrate 110 may be a transparent substrate such as fused silica (SiO₂) relatively free of defects, calcium fluoride, or other suitable material.

The mask 100 includes a phase shift layer 120 disposed on the substrate 110. The phase shift layer 120 is designed to provide a phase shift to a radiation beam used to fabricate a semiconductor wafer during a lithography process. The phase shift layer 120 may have a thickness such that a radiation beam directed toward and through the phase shift layer 120 has a phase shift relative to the radiation beam directed through the air. The radiation beam is used on the mask 100 to form a pattern on a semiconductor wafer during a photolithography process. The radiation beam may be ultraviolet and/or can be extended to include other radiation beams such as ion beam, x-ray, extreme ultraviolet (EUV), deep ultraviolet (DUV), and other proper radiation energy. The thickness of the phase shift layer 120 may have a tolerance of plus or minus about 15 degrees in terms of optical phase. In one embodiment, the phase shift layer 120 has a phase shift about 180 degrees. More specifically, the phase shift layer 120 may have a thickness about λ/[2(n−1)], wherein λ is the wavelength of the radiation beam projected on the mask 100 during a photolithography process, and n is refractive index of the phase shift layer 120 relative to the specified radiation beam. In another embodiment, the phase shift layer 120 may have a phase shift ranging between about 120 degrees and 240 degrees. Specifically, the phase shift layer 120 may have a thickness ranging between λ/[3(n−1)] and 2λ/[3(n−1)] to realize a desired phase shift. The phase shift layer 120 may have a transmission less than one (or 100%) and more than zero. In another example, the phase shift layer 120 may have a transmission higher than about 5%. The phase shift layer 120 may include metal silicide such as MoSi or ToSi₂, metal nitride, iron oxide, inorganic material, other materials such as Mo, Nb₂O₅, Ti, Ta, CrN, MoO₃, MoN, Cr₂O₃, TiN, ZrN, TiO₂, TaN, Ta₂O₅, SiO₂, NbN, Si₃N₄, ZrN, Al₂O₃N, Al₂O₃R, or combinations thereof. The method of forming the phase shift layer 120 may include chemical vapor deposition (CVD), physical vapor deposition (PVD), atomic layer deposition (ALD), plating, and/or other suitable processes.

The mask 100 includes an attenuating layer 130 disposed on the phase shift layer 120. The attenuating layer 130 is designed as an absorption layer and is opaque to a radiation beam used for lithography processing. The attenuating layer 130 has a transmission less than that of the phase shift layer 120. In one embodiment, the attenuating layer 130 has a transmission less than about 30%. The attenuating layer 130 may utilize a material different from that of the phase shift layer 120. The attenuating layer 130 may be formed using a process similar to those used to form the phase shift layer 120. The attenuating layer 130 may include Cr, CrN, Mo, Nb₂O₅, Ti, Ta, CrN, MoO₃, MoN, Cr₂O₃, TiN, ZrN, TiO₂, TaN, Ta₂O₅, SiO₂, NbN, Si₃N₄, ZrN, Al₂O₃N, Al₂O₃R, or a combination thereof. The method of forming the attenuating layer 130 may include CVD, PVD, ALD, plating, and/or other suitable processes similar to those used to form the phase shift layer.

A resist layer 140 is formed on the attenuating layer 130 for lithography patterning. The resist layer 140 can be formed by a spin-on coating method. The resist layer 140 may include chemical amplification resist (CAR).

Referring to FIG. 1b, the resist layer 140 is a positive resist and is patterned to form various openings such as openings 140a and 140b, designed according to aspects of the present disclosure, using a conventional process or a future developed technique. The attenuating layer 130 is exposed within the openings 140a and 140b. In one example, the photolithography process includes soft baking, mask aligning, exposing, post-exposure baking, developing resist, and hard baking.

Referring to FIG. 1c, the attenuating layer 130 is etched through the patterned resist layer 140 to form various openings 130a and 130b in the attenuating layer 130 within the openings 140a and 140b. The phase shift layer 120 is therefore exposed within the openings 130a and 130b. The etchant to etch the attenuating layer 130 may be chosen or designed to have a higher etching selectivity over the phase shift layer 120. The etchant may include halogens species such as fluorine, chlorine and bromine. The etch selectivity is preferred to be no less than about 10. The patterned resist layer 140 is removed after the etching of the attenuating layer 130, using either wet stripping or plasma ashing.

Referring to FIG. 1d, the phase shift layer 120 is etched using the etched attenuating layer 130 as a hardmask. This etching transfers the pattern of the attenuating layer 130 to the phase shift layer 120 resulting in openings 130a and 130b being patterned into the phase shift layer 120. The etchant to etch the phase shift layer 120 is selected to cause etching of the phase shift layer 120 without affecting the remaining portions of the attenuating layer 130. As noted above, the patterned resist layer 140 may be removed after the etching of the attenuating layer 130. Alternately, the patterned resist layer 140 may be removed after etching of the phase shift layer 120.

Referring to FIGS. 1e and 1f, another resist layer 150 is coated or otherwise deposited on the patterned attenuating layer 130. The resist layer 150 is then further patterned to form a pattern 150a in the resist layer 150 to expose the underlying phase shift layer 120 within the pattern 150a. The resist layer 150 and the patterning thereof may be substantially similar to the resist layer 140 and the patterning thereof. Moreover, in one embodiment, resist layer 150 is a negative resist, which as will be described below, can be exploited to reduce subsequent exposure time and increase fabrication throughput.

The resist layer 150 is patterned and then developed to define a pattern 150a in which portions of the attenuating layer 130 are covered by the resist layer 150 and other portions are not. In one embodiment, an electron beam writer is used to pattern resist layer 150; although, it is contemplated that other lithography techniques and tools may be used. However, an electron beam writer significantly reduces exposure time of resist layer 150 when compared to raster based lithography tools, such as a laser writer.

Referring to FIG. 1g, after patterning of the resist layer 150, the remaining portions of the attenuating layer 130 are removed, e.g. etched. As noted above, resist layer 150 is a negative resist. As such, resist layer 150 becomes insoluble when exposed. On the other hand, the remaining portions of the attenuating layer 130 remain soluble and therefore may be removed using a known or to be developed etchant, or other removal techniques.

As shown in FIG. 1h, following etching of the attenuating layer 130, the patterned resist layer 150 is removed using either wet stripping, plasma ashing, or other known or to-be-developed technique. This results in a mask 100 with a patterned phase shift layer 120 above a transparent substrate 120 and with a portion of the patterned phase shift layer covered by a patterned attenuating layer 130.

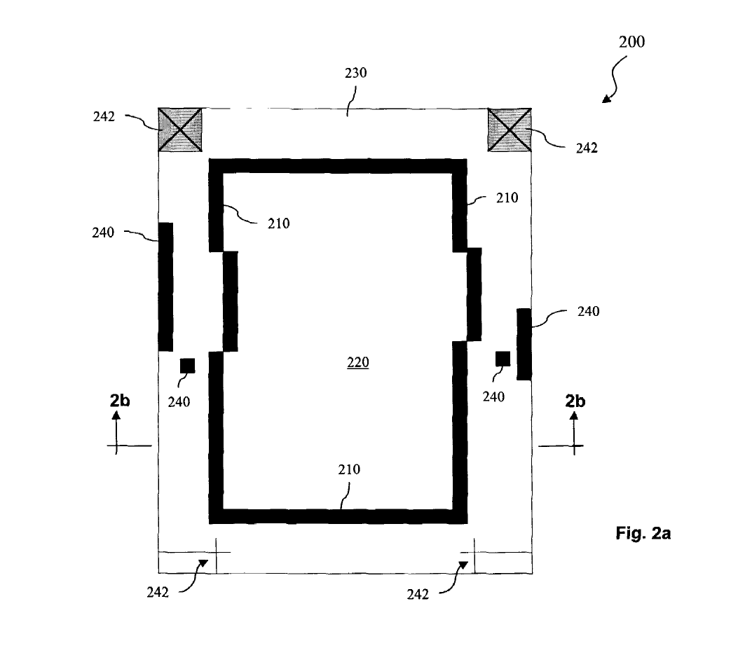

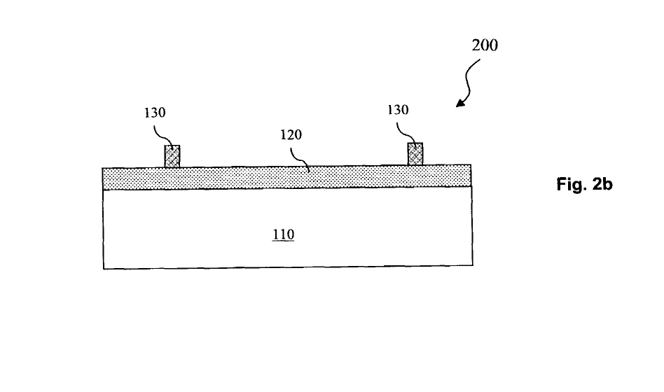

FIGS. 2a and 2b are top and sectional views, respectively, of a mask 200 according to one embodiment of the present disclosure and constructed in accordance with the fabrication process described with respect to FIGS. 1a-1h. Mask 200 has a mask pattern 210 that defines a device pattern area 220. The device pattern area 220 contains phase shift material 120 above a mask substrate 110, such as quartz. The mask pattern area 210 contains patterned attenuating material 130, such as chrome, with underlying phase shift material 120 and the mask substrate 110. As shown, the mask pattern 210 may not extend to the edges of the mask 200. That is, an administrative pattern area 230 may be defined between the edges of the mask and the mask pattern 210. This administrative pattern area 230, in the exemplary figure, predominantly contains phase shift material 120 on the mask substrate 110. Portions of the administrative pattern area 230 contain mask features 240. Mask features 240 are used for masking administrative elements onto a IC wafer, such as bar codes, alignment keys, etc. Alignment markings 242 may also be defined in the mask 200 itself for aligning the mask 200 with an IC wafer for printing thereof.

In one embodiment, the present disclosure is directed to a method that includes providing a substrate having a phase shift layer above the substrate and an attenuating layer formed above the phase shift layer. A first exposure is performed of the phase shift layer and the attenuating layer. The phase shift layer and the attenuating layer are then etched to define a device pattern area. A second exposure is performed of the attenuating layer, which exposes only portions of the attenuating layer that are to remain on the substrate after subsequent etching. Subsequent etching steps are then carried out to fabricate the mask.

In another embodiment, a photomask is presented that includes a substrate and a device pattern area above the substrate. The photomask has a mask pattern defining boundaries of the device pattern area and an administrative pattern area defining boundaries of the mask pattern.

It is to be understood that the foregoing disclosure provides different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not itself dictate a relationship between various embodiments and/or configurations discussed.

What is claimed is:

1. A method comprising:
providing a substrate having a phase shift layer above the substrate and an attenuating layer formed above the phase shift layer;
performing a first exposure of the phase shift layer and the attenuating layer;
etching the phase shift layer and the attenuating layer to define a device pattern area;
performing a second exposure of the attenuating layer, wherein the second exposure exposes only portions of the attenuating layer that are to remain on the substrate after subsequent etching; and
carrying out the subsequent etching.

2. The method of claim 1 wherein performing a first exposure includes patterning a first mask layer formed above the attenuating layer and the phase shift layer, and wherein performing the second exposure includes:
forming a second mask layer above the attenuating layer; and
patterning the second mask layer such that only a portion of the attenuating layer is covered by the second mask layer.

3. The method of claim 2 wherein forming the second mask layer includes coating a negative photoresist layer above the attenuating layer.

4. The method of claim 2 wherein patterning the second mask layer includes exposing the second mask layer with an electron-beam writer.

5. The method of claim 2 wherein the first mask layer includes a first photoresist layer.

6. The method of claim 2 wherein the attenuating layer is a metal layer.

7. The method of claim 6 wherein the metal layer includes chromium.

8. The method of claim 7 wherein the metal layer is chromium oxide.

9. The method of claim 2 wherein the second mask layer includes a second photoresist layer.

10. A photomask comprising:
a substrate;
a device pattern area above the substrate;
a mask pattern defining boundaries of the device pattern area; and
an administrative pattern area defining boundaries of the mask pattern.

11. The photomask of claim 10 wherein the mask pattern comprises chromium.

12. The photomask of claim 11 wherein the mask pattern is formed of chromium oxide.

13. The photomask of claim 10 wherein the device pattern comprises phase shifting material.

14. The photomask of claim 13 wherein the phase shifting material comprises molybdenum silicide.

15. The photomask of claim 10 wherein the administrative pattern area includes a mask feature.

16. The photomask of claim 15 wherein the mask feature provides masking for one of a bar code and an alignment key.

17. The photomask of claim 10 formed by:
providing a substrate having a phase shift layer above the substrate and an attenuating layer formed above the phase shift layer;
performing a first exposure of the phase shift layer and the attenuating layer;
etching the phase shift layer and the attenuating layer to define a device pattern area;
performing a second exposure of the attenuating layer, wherein the second exposure exposes only portions of the attenuating layer that are to remain on the substrate after subsequent etching; and
carrying out the subsequent etching.

18. The photomask of claim 17 wherein performing the first exposure includes patterning a first mask layer formed above the attenuating layer and the phase shift layer, and wherein performing the second exposure includes:
forming a second mask layer above the attenuating layer; and
patterning the second mask layer such that only a portion of the attenuating layer is covered by the second mask layer.

19. The photomask of claim 10 wherein the mask pattern is defined using an electron beam writer.
